(19) United States
(12) Patent Application Publication
(10) Pub. No.: US 2023/0384384 A1
(43) Pub. Date: Nov. 30, 2023

(54) METHOD AND DEVICE FOR NONDESTRUCTIVE DETECTION OF ELECTRODE LITHIUM INTERCALATION OF LITHIUM ION BATTERY, AND BATTERY MANAGEMENT SYSTEM THEREWITH

(71) Applicant: SHANGHAI MAKESENS ENERGY STORAGE TECHNOLOGY CO., LTD., Shanghai (CN)

(72) Inventors: Pingchao Hao, Shanghai (CN); Weikun Wu, Shanghai (CN); Xiaohua Chen, Shanghai (CN); Danfei Gu, Shanghai (CN); Xiao Yan, Shanghai (CN); Enhai Zhao, Shanghai (CN); Pei Song, Shanghai (CN); Peng Ding, Shanghai (CN)

(21) Appl. No.: 18/198,332

(22) Filed: May 17, 2023

(30) Foreign Application Priority Data
May 27, 2022 (CN) 202210587756.5

(51) Int. Cl. G01R 31/3835; H01M 10/44; H02J 7/00; G01R 31/367

(52) U.S. Cl. CPC G01R 31/3835; H01M 10/44; H02J 7/0047; G01R 31/367

(57) ABSTRACT

The invention discloses a method and a device for detecting the lithium intercalation amounts of lithium ion battery electrodes and a battery management system therewith. The method comprises acquiring lithium intercalation ranges of electrodes; obtaining a first characteristic point and a second characteristic point on the characteristic curves of electrode potentials; obtaining a small current rate charging and discharging curve; calculating the charging capacity-open circuit voltage curve; obtaining the third characteristic point and the fourth characteristic point on the charging capacity-open circuit voltage curve; and calculating the amounts of the lithium intercalations of the positive and negative electrodes based on relationships of the characteristic points, the electrode lithium intercalations and the charging capacity The invention can realize nondestructive detection of the amounts of lithium intercalation in the positive and negative electrodes of the lithium-ion battery without disassembly of the lithium-ion battery.

### CROSS-REFERENCE TO RELATED PATENT APPLICATION

This application claims priority to and the benefit of Chinese Patent Application No. 202210587756.5, filed May 27, 2022, which are incorporated herein in their entireties by reference.

### FIELD OF THE INVENTION

The invention relates generally to the field of lithium ion batteries, and more particularly to a method and a device for nondestructive detection of electrode lithium intercalation amount of lithium ion battery, and a battery management system.

### BACKGROUND OF THE INVENTION

In recent years, due to the increase of fossil energy crisis and environmental problems, new energy technologies such as wind energy technology and solar energy technology have developed rapidly. Due to the instability of the output power of the new energy system, it is necessary to introduce an energy storage system, and lithium-ion batteries have been widely used. In order to ensure the safety and reliability of lithium-ion batteries in long-term use, a battery management system (BMS) consisting of software and hardware is required to manage them. The currently widely used BMS are all developed based on the equivalent circuit model (ECM). Due to the limited predictive ability of ECM, the design of battery operation strategy is based on simple safety constraints, such as: a charge cutoff voltage, a discharge cutoff voltage, a maximum current, and the like.

However, the terminal voltage cannot fully reflect the internal state of the battery, especially at high currents, due to the large overpotential, which greatly increases or decreases the terminal voltage of the battery during charging and discharging. With the improvement of hardware computing power, a new type of more intelligent and advanced BMS based on electrochemical model (EM) is applied. Because EM can fully reflect the internal state of the battery, such as: positive and negative lithium ion concentration distribution, potential distribution, overpotential, etc., the capacity of lithium-ion batteries can be maximized to achieve greater economic benefits. The EM involves a large number of coupled partial differential equations, especially dozens of physical parameters, which makes the EM model limited in practical applications.

In order to obtain these parameters, such as the amount of lithium intercalation of the positive and negative electrodes, it is generally necessary to disassemble the battery and conduct experiments to obtain the parameters, but is these methods are usually very complicated and time-consuming, and can only obtain one-time parameters. Related parameters cannot be monitored in the using process of the battery.

Therefore, a heretofore unaddressed need exists in the art to address the aforementioned deficiencies and inadequacies.

### SUMMARY OF THE INVENTION

In view of the above-noted shortcomings of the prior art, one of the objectives of this invention is to provide a method for detecting the lithium intercalation amount of the lithium ion battery electrodes, a detection device and a battery management system based on the detection method, which are nondestructive to the lithium ion battery and can be repeatedly carried out.

In order to achieve the above objectives, one aspect of the invention provides a method for detecting amounts of lithium intercalation in electrodes of a lithium ion battery, which is used for nondestructive electrode detection of the lithium ion battery.

The method includes acquiring a range of a positive electrode lithium intercalation amount and a range of a negative electrode lithium intercalation amount in a set charge-discharge cycle of the lithium ion battery; obtaining at least one first characteristic point (x₁, Vₚ₁) on a first characteristic curve Vₚ(x) of a potential Vₚ of a positive electrode material and a lithium intercalation amount x of the positive electrode within the range of the positive electrode lithium intercalation amount, and obtaining at least one second characteristic point (y₂, Vₙ₂) on a second characteristic curve Vₙ(y) of a potential Vₙ of a negative electrode material and a lithium intercalation amount y of the negative electrode within the range of the negative electrode lithium intercalation amount; obtaining a relation curve Q(V_{ocv}) or V_{ocv}(Q) of a charging capacity and an open-circuit voltage of the lithium ion battery; obtaining a third characteristic point (V_{ocv1}, Q₁) on the relation curve Q(V_{ocv}) or V_{ocv}(Q) corresponding to the first characteristic point, and a fourth characteristic point (V_{ocv2}, Q₂) on the curve Q(V_{ocv}) or V_{ocv}(Q) corresponding to the second characteristic point; and calculating parameters of the lithium intercalations of the positive and negative electrodes including: calculating a positive electrode full discharge lithium intercalation amount x₀, a positive electrode full charge lithium intercalation amount x₁₀₀%, a negative electrode full discharge lithium intercalation amount y₀, and a negative electrode full charge lithium intercalation amount y_{100%}, according to the data of the first characteristic point, the second characteristic point, the third characteristic point, and the fourth characteristic point.

In one embodiment, the step of calculating the parameters of the lithium intercalation amounts of the positive and negative electrodes comprises solving equations of:

$$\{ \begin{matrix}{Q}_{1} = \frac{{x}_{1} - {x}_{0}}{{x}_{100 \%} - {x}_{0}} \\ {Q}_{2} = \frac{{x}_{2} - {x}_{0}}{{x}_{100 \%} - {x}_{0}}\end{matrix} , \{ \begin{matrix}{Q}_{1} = \frac{{y}_{1} - {y}_{0}}{{y}_{100 \%} - {y}_{0}} \\ {Q}_{2} = \frac{{y}_{2} - {y}_{0}}{{y}_{100 \%} - {y}_{0}}\end{matrix} ,$$

wherein x₂ is the positive electrode lithium intercalation amount obtained according to the first characteristic curve Vₚ(x) after a positive electrode potential Vₚ₂=V_{ocv2}+Vₙ₂ corresponding to the fourth characteristic point is calculated, and y₁ is the negative electrode lithium intercalation amount obtained according to the second characteristic curve Vₙ(y) after a negative electrode potential Vₙ₁=Vₚ₁−V_{ocv1} corresponding to the third characteristic point is calculated,

In one embodiment, the first characteristic point (x₁, Vₚ₁) is obtained through extremum points of a differential curve dVₚ(x)/dx of the first characteristic curve Vₚ(x); and the second characteristic point (y₂, Vₙ₂) is obtained through extremum points of a differential curve dVₙ(y)/dy of the second characteristic curve Vₙ(y); the third characteristic point (V_{ocv1}, Q₁) is obtained by comparing a differential curve of the curve Q(V_{ocv}) with the differential curve dVₚ(x)/dx of the is first characteristic curve Vₚ(x), or comparing a differential curve of the curve V_{ocv}(Q) with the differential curve dVₚ(x)/dx of the first characteristic curve Vₚ(x); and the fourth characteristic point (V_{ocv2}, Q₂) is obtained by comparing a differential curve of the curve Q(V_{ocv}) with the differential curve dVₙ(y)/dy of the second characteristic curve Vₙ(y), or comparing a differential curve of the curve V_{ocv}(Q) with the differential curve dVₙ(y)/dy of the second characteristic curve Vₙ(y).

In one embodiment, when the differential curve dVₚ(x)/dx of the first characteristic curve Vₚ(x) has multiple extremum points, the first characteristic point (x₁, Vₚ₁) is obtained according to one extremum point having the largest or smallest value; and when the differential curve dVₙ(y)/dy of the second characteristic curve Vₙ(y) has multiple extremum points, the second characteristic point (y₂, Vₙ₂) is obtained according to one extremum point having the largest or smallest value. In one embodiment, the step of obtaining the curve Q(V_{ocv}) V_{ocv}(Q) of the charging capacity and the open-circuit voltage of the lithium ion battery comprises: measuring a terminal voltage curve of the lithium ion battery in the charging and discharging process with a small current rate, and approximating the terminal voltage curve as an open-circuit voltage curve V_{ocv}(t) of the lithium ion battery, wherein t is the charging and discharging time; obtaining a charging capacity curve Q(t) of the lithium ion battery by integrating the charging and discharging current I; and obtaining the curve Q(V_{ocv}) or V_{ocv}(Q) according to the open circuit voltage curve V_{ocv}(t) and the charging capacity curve Q(t) of the lithium ion battery. In one embodiment, the charging and discharging current I adopted in the charging and discharging process with the small current rate is a constant current, and the charging and discharging rate is not greater than C/20. The charging and discharging process with the small current rate includes small current rate charging processes and small current rate discharging processes; and the open circuit voltage curve V_{ocv}(t) and the charging capacity curve Q(t) are obtained by averaging data obtained from at least one of the small current rate charging processes and at least one of the small current discharge processes.

In one embodiment, the first characteristic curve Vₚ(x) and the second characteristic curve Vₙ(y) are obtained by half-cell testing, or by known characteristic curves of the positive electrode material and the negative electrode material.

In one embodiment, in the charging and discharging process with a small current rate, the lithium ion battery is placed in an environment with a constant temperature and a constant humidity.

Another aspect of the invention also provides a lithium-ion battery electrode lithium intercalation detection device, which uses any of the above-mentioned detection methods for the lithium-ion battery positive and negative lithium intercalation detection methods to perform non-destructive electrode detection on the lithium-ion battery.

Yet another aspect of the invention also provides a battery management system, including the aforementioned device for detecting the amount of lithium intercalated in the positive and negative electrodes of the lithium-ion battery, and the function of the battery management system includes non-destructive electrode detection of the lithium-ion battery.

Various embodiments of the invention have at least one of the following technical effects:
1. By means of the characteristic points on the potential curves of the positive and negative electrode materials, combined with the corresponding characteristic points on the small rate charging and discharging curves of the lithium-ion battery, an equation set is established to solve the lithium intercalation amounts of the positive and negative electrodes of the lithium ion battery, which does not need to disassemble the lithium ion battery and can be repeatedly carried out.
2. Establishing an equation set by a method corresponding to the characteristic points, and solving the equations to obtain the lithium intercalation amount of the positive electrode and the negative electrode, which can be used for both a common lithium ion battery and a multi-element lithium ion battery adopting composite electrode materials.
3. By completing the charging and discharging process with a small current rate in a constant temperature and humidity environment, the measurement results are more accurate. When applied to a vehicle, the testing environment can be realized by using the conventional BMS thermal management system.
4. By averaging the measurement data obtained during the small current rate charging process and the small current rate discharging process, the error caused by the charging and discharging overvoltage can be further reduced.
5. By providing sufficient electrode lithium intercalation parameters for the electrochemical model, the BMS can realize more accurate monitoring and management on the lithium ion battery.

### BRIEF DESCRIPTION OF THE DRAWINGS

The accompanying drawings illustrate one or more embodiments of the invention and, together with the written description, serve to explain the principles of the invention. The same reference numbers may be used throughout the is drawings to refer to the same or like elements in the embodiments.

FIG. 1 is schematically a flow chart of a method for detecting lithium intercalation amounts of electrodes of a lithium ion battery according to one embodiment of the invention.

FIG. 2 is a schematic illustration of a first characteristic curve according to one embodiment of the invention.

FIG. 3 is a second characteristic curve diagram according to one embodiment of the invention.

FIG. 4 is a schematic representation of a differential curve of the first characteristic of FIG. 2.

FIG. 5 is a schematic representation of a differential curve of the second characteristic of FIG. 3.

FIG. 6 is a plot of the measured terminal voltage of a lithium ion battery during small current rate discharging according to one embodiment of the invention.

FIG. 7 is a small current rate discharging curve Q(V_{ocv}) according to one embodiment of the invention. FIG. 8 is a differential curve of the small current rate discharge curve Q(V_{ocv}) according to one embodiment of the invention.

### DETAILED DESCRIPTION OF THE INVENTION

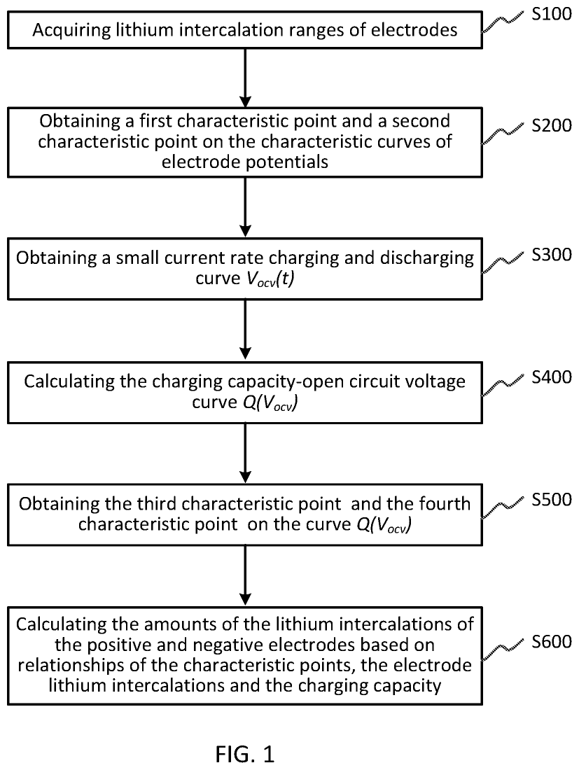

Embodiments of the invention are described below through specific examples in conjunction with the accompanying drawings in FIGS. 1-8, and those skilled in the art can easily understand other advantages and effects of the invention from the content disclosed in this specification. The invention can also be implemented or applied through other different specific implementations, and various modifications or changes can be made to the details in this specification is based on different viewpoints and applications without departing from the spirit of the invention. It should be noted that, in the case of no conflict, the following embodiments and features in the embodiments can be combined with each other.

It should be noted that the drawings provided in the following embodiments are merely illustrative in nature and serve to explain the principles of the invention, and are in no way intended to limit the invention, its application, or uses. Only the components related to the invention are shown in the drawings rather than the number, shape and size of the components in actual implementations. For components with the same structure or function in some figures, only one of them is schematically shown, or only one of them is marked. They do not represent the actual structure of the product. Dimensional drawing, the type, quantity and proportion of each component can be changed arbitrarily in its actual implementations. More complicate component layouts may also become apparent in view of the drawings, the specification, and the following claims.

The terminology used herein is for the purpose of describing particular embodiments only and is not intended to be limiting of the invention. As used herein, “a” not only means “only one”, but also means “more than one”. The term “and/or” used in the description of the present application and the appended claims refers to any combination and all possible combinations of one or more of the associated listed items, and includes these combinations. The terms “first”, “second”, etc. are only used for distinguishing descriptions, and should not be construed as indicating or implying relative importance.

Unless otherwise clearly defined, the terms “installation” and “connection” should be interpreted in a broad sense, for example, it may be a fixed connection, a detachable connection, or an integral connection; it may be a mechanical connection, It can also be an electrical connection; it can be directly connected, or indirectly connected through an intermediary, or it can be the internal communication of two components. Those of ordinary skill in the art can understand the specific meanings of the above terms in this application in specific situations.

As shown in FIG. 1, the method for detecting an amount of lithium intercalation in a lithium ion battery electrode is shown according to one embodiment of the invention, which is used for nondestructive electrode detection of a lithium ion battery. The method includes steps S100 to S600. The specific operations of the steps are specifically described below.

At step S100, acquiring lithium intercalation ranges of electrodes. Specifically, a positive electrode lithium intercalation range and a negative electrode lithium intercalation range in a set charge-discharge cycle of the lithium ion battery are obtained. The set charge-discharge cycle refers to a discharge cycle in which the open-circuit voltage (OCV) of the lithium ion battery is discharged from the charge cutoff voltage to the discharge cutoff voltage, or a charge cycle in which the lithium ion battery is charged from the discharge cutoff voltage to the charge cutoff voltage. For convenience of the description, the battery charge capacity (amount) is normalized in this specification: when the lithium ion battery is charged to the charge cutoff voltage, the battery charge capacity corresponds to a full state, the corresponding battery state of charge (SOC) is 1, or the battery charge capacity Q=1. When the lithium ion battery is discharged to the discharge cutoff voltage, the corresponding SOC is 0, or the battery charge capacity Q=0. In order to prevent capacity loss caused by overcharge and overdischarge of the lithium ion battery, lithium intercalation ranges of the positive and negative electrodes in the charge-discharge cycles need to be set. Therefore, only the electrode parameters within the above ranges of lithium intercalation amounts need to be considered.

S200, obtaining a first characteristic point and a second characteristic point is on the characteristic curves of electrode potentials. Specifically, within the range of the positive electrode lithium intercalation amount, at least one first characteristic point (x₁, Vₚ₁) is obtained on a first characteristic curve Vₚ(x) of a potential Vₚ of a positive electrode material and a lithium intercalation amount x of the positive electrode; and within the range of the negative electrode lithium intercalation amount, at least one second characteristic point (y₂, Vₙ₂) is obtained on a second characteristic curve Vₙ(y) of a potential Vₙ of a negative electrode material and a lithium intercalation amount y of the negative electrode. The intercalated matter in the positive and negative electrodes can undergo a reversible phase change during the lithium intercalation or lithium deintercalation process of the positive and negative electrode materials, and the lithium intercalation amounts and electrode potentials corresponding to the phase transition point constitute the characteristic points of the corresponding positive and negative electrode materials, which have specificity and repeatability. Meanwhile, the difference between the lithium intercalation potentials of the positive and negative electrodes is the open circuit voltage of the lithium ion battery, and the lithium intercalation is related to the state of charge (SOC) of the lithium ion battery. Therefore, the lithium intercalation parameters of the positive and negative electrodes can be calculated by utilizing the characteristic points and combining with the measurement data in the charging and discharging process.

S300, obtaining a small current rate charging and discharging curve V_{ocv}(t). Specifically, a terminal voltage curve of the lithium ion battery is measured during charging and discharging at a small current rate. The terminal voltage curve is approximated as an open-circuit voltage curve V_{ocv}(t) of the lithium ion battery, wherein t is the charging and discharging time. A charging capacity curve Q(t) of the lithium ion battery is obtained by integrating the charging and discharging current I.

As used in the disclosure, the letter Q represents the charging capacity of the battery, and the letter C represents the capacity of the battery, which are related. The former is used to represent the charging capacity of the lithium ion battery relative to the fully discharged state, and the latter is equivalent to the capacity of the battery when charged to the charging cutoff voltage, that is, the fully charged state. Each variable in the disclosure is represented by a letter or a letter with a subscript, such as x represents the lithium intercalation amount of the positive electrode; the subscript p represents the positive electrode, the subscript n represents the negative electrode, and the subscript ocv represents the open circuit voltage. See Table 1 below for details. For the sake of brevity, when a certain variable also serves as an independent variable in an explanatory statement or in a complex formula, the independent variable corresponding to the variable, such as time t, is not indicated. For example, the lithium intercalation amount x(t) of the positive electrode is a variable with the charge and discharge time t as the independent variable, but when it is not necessary or the lithium intercalation amount of the positive electrode itself is used as the independent variable, it is simply expressed by x and no longer indicates the independent variable t. When each variable has a digital subscript, it refers to the specific value of the variable at a certain characteristic point, such as x₁ represents the positive electrode lithium intercalation amount of the first characteristic point, or Q₁ represents the battery charging capacity of the third characteristic point (For the third characteristic point, refer to step S400 for details).

The small current rate charging and discharging refers to the charging and discharging current I is much smaller than that at the standard charging and discharging rate. Since the charging and discharging rate is very small, the overpotential of the lithium ion battery can be ignored. At this time, the terminal voltage curve of the lithium ion battery can be accurately used as the open-circuit voltage curve V_{ocv}(t) of the lithium ion battery, which satisfies the following relationship: V_{ocv}(t)=Vₚ(t)−Vₙ(t), or the open circuit voltage OCV of a lithium ion battery is equal to the subtraction of the negative potential from the positive potential. At the same time, because there is a corresponding relationship between the integral of the charging and discharging current I on the charging and discharging time t and the lithium ion migration amount, i.e., the amount of lithium intercalation or lithium deintercalation of the positive and negative electrodes, that is, a corresponding relationship exists with the charging capacity of the battery. Therefore, the battery charging capacity curve can be obtained by integrating the charge and discharge current I.

At step S400, calculating the charging capacity-open circuit voltage curve Q(V_{ocv}) or the open circuit voltage-charging capacity curve V_{ocv}(Q). Since both the open circuit voltage curve V_{ocv}(t) and the charging capacity curve Q(t) are functions of time, the charging capacity-open circuit voltage curve Q(V_{ocv}) or the open circuit voltage-charging capacity curve V_{ocv}(Q) can be simply calculated.

At step S500, obtaining the third characteristic point (V_{ocv1}, Q₁) and the fourth characteristic point (V_{ocv2}, Q₂) on the curve Q(V_{ocv}) or V_{ocv}(Q).

Specifically, taking the curve Q(V_{ocv}) as an example, the open circuit voltage V_{ocv}(t)=Vₚ(t)−Vₙ(t), and the first characteristic curve Vₚ(x) has the first characteristic point (x₁, Vₚ₁), the second characteristic curve Vₙ(y) has the second characteristic point (y₂, Vₙ₂), and the amount of the lithium intercalation x of the to positive electrode and the amount of the lithium intercalation y of the negative electrode correspond to the battery charging capacity Q. Due to the specificity of the above characteristic points, the third characteristic point (V_{ocv1}, Q₁) corresponding to the first characteristic point (x₁, Vₚ₁), and the fourth characteristic point (V_{ocv2}, Q₂) corresponding to the second characteristic point is (y₂, Vₙ₂) can be determined on the curve Q(V_{ocv}). When the state of the lithium ion battery is at the third characteristic point, the amount of the positive electrode lithium intercalation x is the amount of the positive electrode lithium intercalation x₁ of the first characteristic point (x₁, Vₚ₁); when the state of the lithium ion battery is at the third characteristic point, the amount of the negative electrode lithium intercalation y is the amount of the negative electrode lithium intercalation y₂ of the second characteristic point.

At step S600, calculating the amounts of the lithium intercalations of the positive and negative electrodes based on relationships of the characteristic points, the electrode lithium intercalations and the charging capacity: calculating a positive electrode full discharge lithium intercalation amount x₀, a positive electrode full charge lithium intercalation amount x_{100%}, a negative electrode full discharge lithium intercalation amount y₀, and a negative electrode full charge lithium intercalation amount y_{100%}, according to the data of the first characteristic point, the second characteristic point, the third characteristic point, and the fourth characteristic point.

In the charging and discharging process at a small current rate, changes in the lithium intercalations of the positive and negative electrodes can be considered to be same, therefore, the state of charge SOC of the battery, which is equivalent to the normalized battery charging capacity Q, can be calculated by the following formula:

$$SOC = Q = \frac{θ - {θ}_{0}}{{θ}_{100 \%} - {θ}_{0}}$$

where θ is the amount of the lithium intercalation in an electrode (positive or negative), θ₀ is the amount of the lithium intercalation in the electrode when discharged to the discharging cutoff voltage, and θ_{100%} is the amount of the lithium intercalation in the electrode when charged to the charging cutoff voltage.

Specifically, step S600 includes: solving the following equations to calculate the positive electrode full discharge lithium intercalation amount x₀, the positive electrode full charge lithium intercalation amount x_{100%}, the negative electrode full discharge lithium intercalation amount y₀, and the negative electrode full charge lithium intercalation amount y_{100%}:

$$\{ \begin{matrix}{Q}_{1} = \frac{{x}_{1} - {x}_{0}}{{x}_{100 \%} - {x}_{0}} \\ {Q}_{2} = \frac{{x}_{2} - {x}_{0}}{{x}_{100 \%} - {x}_{0}}\end{matrix} , \{ \begin{matrix}{Q}_{1} = \frac{{y}_{1} - {y}_{0}}{{y}_{100 \%} - {y}_{0}} \\ {Q}_{2} = \frac{{y}_{2} - {y}_{0}}{{y}_{100 \%} - {y}_{0}}\end{matrix} ,$$

wherein x₂ is the positive electrode lithium intercalation amount obtained according to the first characteristic curve Vₚ(x) after a positive electrode potential Vₚ₂=V_{ocv2}+Vₙ₂ corresponding to the fourth characteristic point is calculated, where V_{ocv2} is the battery open circuit voltage of the fourth characteristic point, and Vₙ₂ is the negative electrode potential of the second characteristic point. y₁ is the negative electrode lithium intercalation amount obtained according to the second characteristic curve Vₙ(y) after a negative electrode potential Vₙ₁=Vₚ₁−V_{ocv1} corresponding to the third characteristic point is calculated, where V_{ocv1} is the battery open circuit voltage of the third characteristic point, and Vₚ₁ is the positive electrode potential of the first characteristic point. In some embodiments, the first characteristic point (x₁, Vₚ₁) is obtained through extremum points of a differential curve dVₚ(x)/dx of the first characteristic curve Vₚ(x). The second characteristic point (y₂, Vₙ₂) is obtained through extremum points of a differential curve dVₙ(y) dy of the second characteristic curve Vₙ(y). The third characteristic point (V_{ocv1}, Q₁) is obtained by comparing a differential curve of the curve Q(V_{ocv}) with the differential curve dVₚ(x)/dx of the first characteristic curve Vₚ(x), or comparing a differential curve of the curve V_{ocv}(Q) with the differential curve dVₚ(x)/dx of the first characteristic curve Vₚ(x). The fourth characteristic point (V_{ocv2}, Q₂) is obtained by comparing a differential curve of the curve Q(V_{ocv}) with the differential curve dVₙ(y)/dy of the second characteristic curve Vₙ(y), or comparing a differential curve of the curve V_{ocv}(Q) with the differential curve dVₙ(y)/dy of the second characteristic curve Vₙ(y).

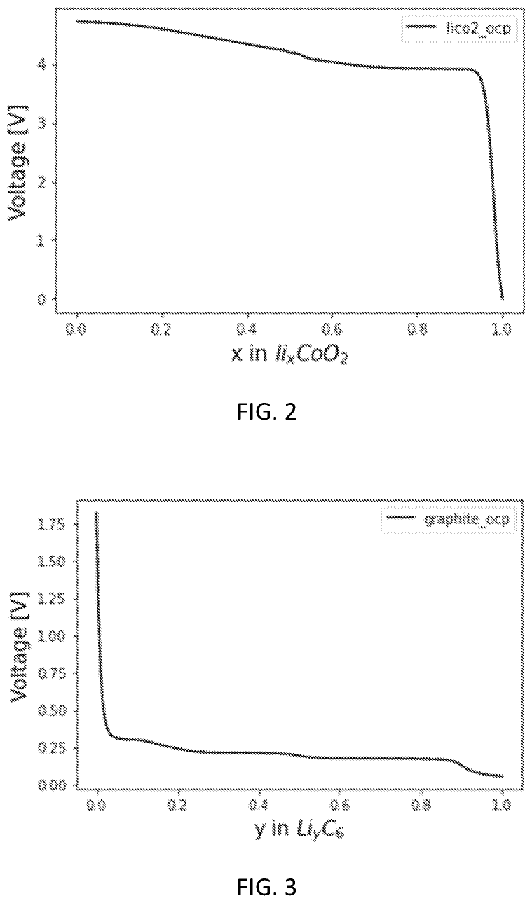

FIG. 2 shows a first characteristic curve of lithium cobaltate LiₓCoO₂ as the positive electrode material. The first characteristic curve can be obtained from literature references. When the lithium cobaltate of the exemplary embodiment is used as the positive electrode material, the lithium intercalation amount of the positive electrode ranges from 0.50 to 0.95. It is shown that the lithium intercalation amount x of the positive electrode has an obvious platform-shaped first characteristic point when it is 0.8-0.9, but it is difficult to determine the exact value of the lithium intercalation amount x of the positive electrode at the first characteristic point. Similarly, FIG. 3 shows the second characteristic curve of lithium intercalation graphite Li_{y}C₆ as the negative electrode material. When the lithium intercalation graphite of this embodiment is used as the negative electrode material, the lithium intercalation amount y of the negative electrode ranges from 0.2 to 0.8. Clearly, the second characteristic curve has a plurality of characteristic points with relatively large slopes within the range of the above-mentioned lithium intercalation amount of the negative electrode, but it is also difficult to determine the exact value of the lithium intercalation amount y of the negative electrode at these characteristic points. Therefore, it is necessary to differentiate the first characteristic curve and the second characteristic curve so as to accurately determine the specific values of the lithium intercalation amount of the first characteristic point and the second characteristic point.

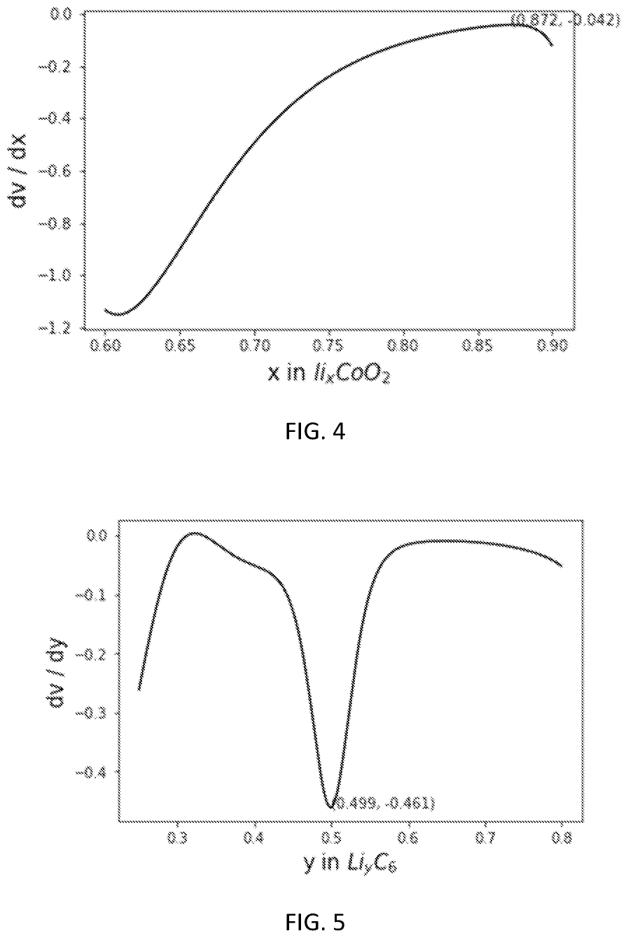

FIGS. 4 and 5 show the differential curve dVₚ(x)/dx of the first characteristic curve Vₚ(x) and the differential curve dVₙy)/dy of the second characteristic curve Vₙ(y), respectively. As shown in FIG. 4, the first characteristic point (x₁, Vₚ₁) corresponds to the peak value of an obvious maximum (i.e., an extremum point having the largest value), and the specific value x₁ of the positive electrode lithium intercalation amount of the first characteristic point (x₁, Vₚ₁) of this embodiment can be accurately determined as x₁=0.872. As shown in FIG. 5, the second characteristic point (y₂, Vₙ₂) corresponds to the peak value of an obvious minimum (i.e., an extremum point having the smallest value), and the specific value y₂ of the negative electrode lithium intercalation amount of the second characteristic point (y₂, Vₙ₂) of this embodiment can be accurately determined as y₂=0.499.

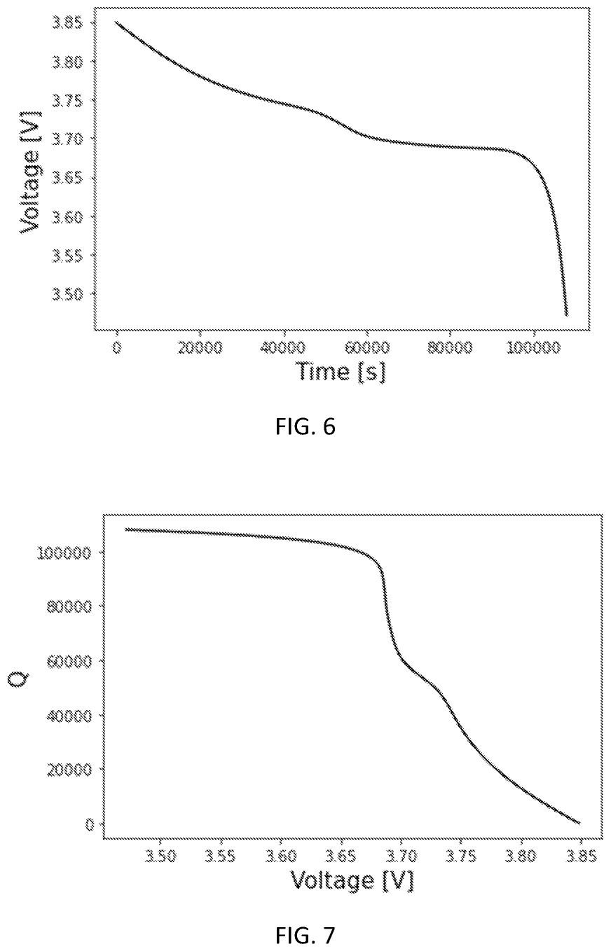

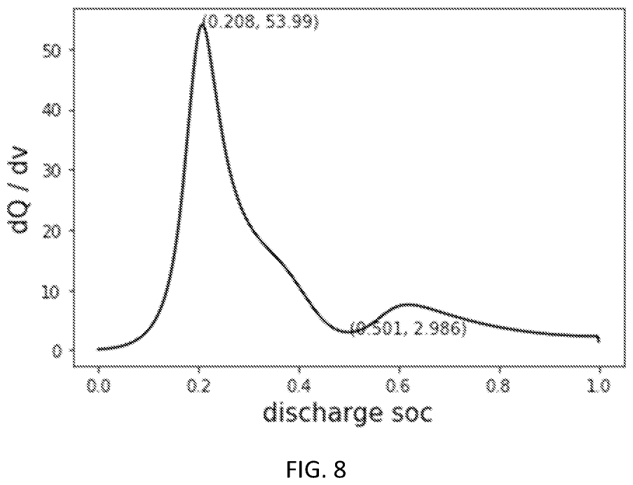

Similarly, from the curve V_{ocv}(t) shown in FIG. 6 (due to the linear relationship between the battery charging capacity Q and the time t in the constant current discharging process, the characteristic points of the curve Q(V_{ocv}) or the curve V_{ocv}(Q) and the characteristic points of the curve V_{ocv}(t) are also one-to-one correspondence), the curve point with a larger slope corresponding to the second feature point and the plateau point corresponding to the first characteristic point can be seen, but the specific value of the battery charging capacity of the third characteristic point and the fourth characteristic point cannot be accurately determined. In the differential curve of the curve Q(V_{ocv}) shown in FIG. 7, it can be accurately determined that the specific value of the battery charging capacity of the third characteristic point (V_{ocv1}, Q₁) corresponding to the first characteristic point is Q₁=0.208, and the specific value of the battery charge of the fourth characteristic point (V_{ocv2}, Q₂) corresponding to the second characteristic point is Q₂=0.501.

In some embodiments, the small current rate charging and discharging is process includes a small current rate charging process and a small current rate discharging process; and the open circuit voltage curve V_{ocv}(t) and the charging capacity curve Q(t) are obtained by averaging data obtained from at least one of the small current rate charging processes and at least one of the small current discharge processes.

Since the positive and negative electrode materials need to overcome the lithium intercalation potential or lithium deintercalation potential of the positive and negative electrode materials during the charging and discharging process, there will be charging and discharging overpotentials. Specifically, during the charging process, the actual measured terminal voltage of the battery at a certain moment will be slightly higher than the open circuit voltage of the battery at this time, while during the discharging process, the actually measured terminal voltage of the battery at a certain moment will be slightly lower than the open circuit voltage of the battery. In the process of charging and discharging at a small current rate, the above-mentioned overpotentials are very small and can be ignored. However, in order to further improve the measurement accuracy, or to reduce the strict requirements on the current of the charging and discharging process, a more accurate open circuit voltage curve V_{ocv}(t) can be obtained by averaging the data obtained during one small current rate charging process and one small current discharging process. It should be noted that the reliability of the measured data can be further improved by averaging the data of multiple measurements.

In some embodiments, when the differential curve dVₚ(x)/dx of the first characteristic curve Vₚ(x) has multiple extremum points, the first characteristic point (x₁, Vₚ₁) is obtained according to one extremum point having the largest or smallest value; and when the differential curve dVₙ(y)/dy of the second characteristic curve Vₙ(y) has multiple extremum points, the second characteristic point (y₂, Vₙ₂) is obtained according to one extremum point having the largest or is smallest value. As shown in FIG. 4, the first characteristic point is an extremum point with the smallest absolute value, and corresponds to the curve point with the flattest (plateau) profile in the range of the lithium intercalation amount of the positive electrode shown in FIG. 2. The second characteristic point shown in FIG. 5 is an extremum point with the largest absolute value, and corresponds to the curve point with the largest slope in the range of the lithium intercalation amount of the negative electrode shown in FIG. 3. When the electrode is made of composite materials, more characteristic points appear in the first characteristic curve or the second characteristic curve, and the selection of the characteristic points with the most obvious characteristics is favorable for determining the third characteristic point and the fourth characteristic point more reliably.

In some embodiments, the charging and discharging current I adopted in the charging and discharging process with the small current rate is a constant current, and the charging and discharging rate is not greater than C/20. In addition to the constant current charging and discharging process, a staged constant current charging and discharging process can also be used, or a non-constant current charging and discharging process with little current fluctuation can be used. When using constant current charging and discharging, the process of obtaining the battery charging capacity curve Q(t) by integrating the charging and discharging current I in step S300 can be replaced by a simple calculation of Q(t)=I*t. In the embodiment shown in FIG. 6, the terminal voltage curve of the battery measured by the small current discharge rate of C/30, and it takes 30 hours to discharge the lithium ion battery from a fully charged state to a fully discharged state. Specifically, the appropriate charging and discharging rate can be selected according to the application scenarios such as measurement accuracy requirements. For example, C/20 is also a commonly used as the small current charging and discharging rate.

In addition to obtaining the relationship curves between the battery charging capacity Q and the open circuit voltage OCV of the lithium ion battery through the charging and discharging process at a small current rate, i.e., the curve Q(V_{ocv}) or V_{ocv}(Q), HPPC (Hybrid Pulse Power Characterization) test can also be used to obtain the above relationship curves.

The following describes the specific calculation process of the lithium intercalation parameters of the positive and negative electrodes in the embodiments shown in FIGS. 2 to 6. As mentioned above, the positive electrode lithium intercalation amount x₁ of the first characteristic point (x₁, Vₚ₁), the negative electrode lithium intercalation amount y₂ of the second characteristic point (y₂, Vₙ₂), the battery charging capacity Q₁ of the third characteristic point (V_{ocv1}, Q₁), and the battery charging capacity Q₁ of the fourth characteristic point (V_{ocv2}, Q₂) are respectively:
x₁=0.872;
y₂=0.499;
Q₁=0.208;
Q₂=0.501;

Further, the curve dQ/dV shown in FIG. 8 is obtained according to the curve Q(V_{ocv}) shown in FIG. 7, and the open circuit voltages of the battery corresponding to the third characteristic point and the fourth characteristic point is obtained. The open circuit voltages V_{ocv1} and V_{ocv2} of the battery corresponding to Q₁ and Q₂ are respectively:
V_{ocv1}=3.687;
V_{ocv2}=3.718;

Further, according to the first characteristic curve and the second characteristic curve, the positive electrode potential Vₚ₁ corresponding to the first characteristic point and the negative electrode potential Vₙ₂ corresponding to the second characteristic point can be obtained.

Vₚ₁=Vₚ(x₁)=3.908V;

Vₙ₂=Vₙ(y₂)=0.196V;

Further, according to the battery open circuit voltage relational formula V_{ocv}(t)=Vₚ(t)−Vₙ(t), the negative potential Vₙ₁ corresponding to the first characteristic point and the positive potential Vₚ₂ corresponding to the second characteristic point can be calculated:

Vₙ₁=Vₚ₁−V_{ocv1}=0.221V;

Vₚ₂=Vₙ₂+V_{ocv2}=3.914V;

Further, according to the negative electrode potential Vₙ₁ corresponding to the first characteristic point and the positive electrode potential Vₚ₂ corresponding to the second characteristic point obtained based on the first characteristic curve and the second characteristic curve in the previous step, the amount of the negative electrode lithium intercalation y₁ corresponding to the first characteristic point and the amount of the positive electrode lithium intercalation x₂ corresponding to the second characteristic point are obtained:

y₁=y(Vₙ₁)=0.351;

x₂=x(Vₚ₂)=0.793;

Further, the above numerical values are substituted into the following equations in step S600, namely,

$$\{ \begin{matrix}{Q}_{1} = \frac{{x}_{1} - {x}_{0}}{{x}_{100 \%} - {x}_{0}} \\ {Q}_{2} = \frac{{x}_{2} - {x}_{0}}{{x}_{100 \%} - {x}_{0}}\end{matrix} , \{ \begin{matrix}{Q}_{1} = \frac{{y}_{1} - {y}_{0}}{{y}_{100 \%} - {y}_{0}} \\ {Q}_{2} = \frac{{y}_{2} - {y}_{0}}{{y}_{100 \%} - {y}_{0}}\end{matrix} ,$$

to obtain:

$$\{ \begin{matrix}0.208 = \frac{0.872 - {x}_{0}}{{x}_{100 \%} - {x}_{0}} \\ 0.501 = \frac{0.793 - {x}_{0}}{{x}_{100 \%} - {x}_{0}}\end{matrix} , \{ \begin{matrix}0.208 = \frac{0.351 - {y}_{0}}{{y}_{100 \%} - {y}_{0}} \\ 0.501 = \frac{0.499 - {y}_{0}}{{y}_{100 \%} - {y}_{0}}\end{matrix} ,$$

Solving the above two binary linear equations, we can get the amount of the positive electrode discharge lithium intercalation x₀, the amount of the positive is electrode full charge lithium intercalation x_{100%}, the amount of the negative electrode discharge lithium intercalation y₀, and the amount of the negative electrode full charge lithium intercalation y_{100%}
x_{0%}=0.928;
x_{100%}=0.658;
y_{0%}=0.246;
y_{100%}=0.751.

In some embodiments, according to the positive electrode full discharge lithium intercalation amount x₀, the positive electrode full charge lithium intercalation amount x_{100%}, the negative electrode full discharge lithium intercalation amount y₀, the negative electrode full charge lithium intercalation amount y_{100%}, the ranges of the positive electrode lithium intercalation amount and the negative electrode insertion amount, the state of health of the electrodes of the lithium ion battery is determined. The capacity loss of the lithium ion battery is partly due to the side reaction between the electrode material and the organic electrolyte, which can usually be reflected in the lithium intercalation parameters of the positive and negative electrodes. By obtaining the lithium intercalation parameters of the positive and negative electrodes, combined with the electrochemical model, the state of health of electrodes of the lithium ion battery can be diagnosed.

In some embodiments, the first characteristic curve Vₚ(x) and the second characteristic curve Vₙ(y) are obtained through a half-cell test. The first characteristic curve and the second characteristic curve shown in FIGS. 2 and 3 are obtained by reference to the literature, i.e., obtained through known characteristic curves of the positive electrode material and the negative electrode material. However, when composite electrode materials or new electrode materials are used, it is necessary to obtain the electrode potential-lithium intercalation characteristic curve of the corresponding electrode material through half-cell test measurements.

In some embodiments, the lithium ion battery is always placed in an environment with constant temperature and constant humidity during charging and discharging at a small current rate. The test temperature can adopt the set battery operating voltage of the common battery management system BMS, such as 45°, while controlling the humidity of the test environment within a lower range. Usually, the lithium ion battery can be placed in an environmental test chamber for relevant measurements, or the lithium ion battery can be connected to the battery management system BMS with a thermal management system for HiL real-time simulation testing.

In one aspect, the invention relates to an electronic device (apparatus) for detecting the lithium intercalation amounts of the electrodes of the lithium ion battery. The electronic device is configured to perform the non-destructive electrode detection of the lithium ion battery by using the method for detection of the lithium ion battery electrode lithium intercalation according to any of the foregoing embodiments. In one embodiment, the electronic device comprises a detection device (module) and a data processing device (module), wherein the detection device is used for realizing the small current charging and discharging cycles of the lithium ion battery and simultaneously measuring related data; the detection device can further comprise a calculation and analysis module for calculating and analyzing the electrode lithium intercalation parameters of the lithium ion battery according to the detection method disclosed above. The battery management system BMS can be connected for carrying out HiL real-time is simulation test on the lithium ion battery.

In another aspect, the invention relates to a battery management system. The battery management system BMS includes the lithium ion battery positive and negative electrode lithium intercalation detection device of the foregoing embodiment, has a small current rate charging function for performing non-destructive electrode detection on the lithium ion battery. The thermal management function of the battery management system BMS realizes the constant temperature and humidity ventilation management of the lithium ion battery. The battery management system BMS monitors and diagnoses the battery state through the electrochemical model and the detection results of the amount of lithium intercalated into the electrodes.

Table 1 lists the symbols and terms used in the specification and their physical meanings.

TABLE 1
symbols and terms and their physical meanings

| Symbol | Physical Meaning |
|---|---|
| BMS | Battery management system |
| ECM | Equivalent circuit model |
| EM | Electrochemical model |
| SOC | State of charge of a battery, or battery state of charge |
| Q, | Charging capacity of a battery, or battery charging capacity |
| Q(t), | |
| Q(V_{ocv}) | |
| Q₁ | Charging capacity of a battery corresponding to a third |
| | characteristic point, or battery charging capacity of a third |
| | characteristic point |
| Q₂ | Charging capacity of a battery corresponding to a fourth |
| | characteristic point, or battery charging capacity of a fourth |
| | characteristic point |
| t | Time |
| C | Capacity of a battery, or battery capacity |
| I | Charging-discharging current, or charging and discharging |
| | current |
| OCV | Open circuit voltage |
| V_{ocv}, | Open circuit voltages of a battery, or battery open circuit |
| V_{ocv}(t), | voltages |
| V_{ocv}(Q) | |
| V_{ocv1} | Open circuit voltage corresponding to a third characteristic |
| | point, or open circuit voltage of a third characteristic point |
| V_{ocv2} | Open circuit voltage corresponding to a fourth characteristic |
| | point, or open circuit voltage of a fourth characteristic point |
| Vₚ, | Potential of a positive electrode, or positive electrode potential |
| Vₚ(t), | |
| Vₚ(x) | |
| Vₙ, | Potential of a negative electrode, or negative electrode |
| Vₙ(t), | potential |
| Vₙ(y) | |
| Vₚ₁ | Potential of a positive electrode corresponding to a first |
| | characteristic point, or positive electrode potential of a first |
| | characteristic point |
| Vₚ₂ | Potential of a positive electrode corresponding to a second |
| | characteristic point, or positive electrode potential of a second |
| | characteristic point |
| Vₙ₁ | Potential of a negative electrode corresponding to a first |
| | characteristic point, or negative electrode potential of a first |
| | characteristic point |
| Vₙ₂ | Potential of a negative electrode corresponding to a second |
| | characteristic point, or negative electrode potential of a second |
| | characteristic point |
| x, | Amount of lithium intercalation of a positive electrode, or |
| x(t) | positive electrode lithium intercalation amount |
| x₀ | Amount of lithium intercalation of a positive electrode when |
| | discharged to a discharging cutoff voltage, or amount of |
| | positive electrode full discharge lithium intercalation, or |
| | positive electrode full discharge lithium intercalation amount |
| x₁ | Amount of positive electrode lithium intercalation |
| | corresponding to a first characteristic point, or positive |
| | electrode lithium intercalation of a first characteristic point |
| x₂ | Amount of positive electrode lithium intercalation |
| | corresponding to a second characteristic point, or positive |
| | electrode lithium intercalation of a second characteristic point |
| x_{100%} | Amount of lithium intercalation of a positive electrode when |
| | charged to a charging cutoff voltage, or amount of positive |
| | electrode full charge lithium intercalation, or positive electrode |
| | full charge lithium intercalation amount |
| y₀ | amount of lithium intercalation of a negative electrode when |
| | discharged to a discharging cutoff voltage, or amount of |
| | negative electrode full discharge lithium intercalation, or |
| | negative electrode full discharge lithium intercalation amount |
| y₁ | Amount of negative electrode lithium intercalation |
| | corresponding to a first characteristic point, or negative |
| | electrode lithium intercalation amount of a first characteristic |
| | point |
| y₂ | Amount of a negative electrode lithium intercalation |
| | corresponding to a second characteristic point, or negative |
| | electrode lithium intercalation amount of a second |
| | characteristic point |
| y_{100%} | Amount of lithium intercalation of a negative electrode when |
| | charged to a charging cutoff voltage, or amount of negative |
| | electrode full charge lithium intercalation, or negative electrode |
| | full charge lithium intercalation amount |
| θ | Amount of lithium intercalation of an electrode (positive or |
| | negative), or lithium intercalation amount of an electrode |
| θ₀ | Amount of lithium intercalation of an electrode when |
| | discharged to a discharging cutoff voltage |
| θ_{100%} | Amount of lithium intercalation of an electrode when charged |
| | to a charging cutoff voltage |
| HiL | Hardware in Loop |

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become to apparent to those skilled in the art to which the invention pertains without departing from its spirit and scope. Accordingly, the scope of the invention is defined by the appended claims rather than the foregoing description and the exemplary embodiments described therein.

What is claimed is:

1. A method for detecting amounts of lithium intercalation in electrodes of a lithium ion battery, used for nondestructive electrode detection of the lithium ion battery, comprising:
acquiring a range of a positive electrode lithium intercalation amount and a range of a negative electrode lithium intercalation amount in a set charge-discharge cycle of the lithium ion battery;
obtaining at least one first characteristic point (x₁, Vₚ₁) on a first characteristic curve Vₚ(x) of a potential Vₚ of a positive electrode material and a lithium intercalation amount x of the positive electrode within the range of the positive electrode lithium intercalation amount, and obtaining at least one second characteristic point (y₂, Vₙ₂) on a second characteristic curve Vₙ(y) of a potential Vₙ of a negative electrode material and a lithium intercalation amount y of the negative electrode within the range of the negative electrode lithium intercalation amount;
obtaining a relation curve Q(V_{ocv}) or V_{ocv}(Q) of a charging capacity and an open-circuit voltage of the lithium ion battery;
obtaining a third characteristic point (V_{ocv1}, Q₁) on the relation curve Q(V_{ocv}) or V_{ocv}(Q) corresponding to the first characteristic point, and a fourth characteristic point (V_{ocv2}, Q₂) on the curve Q(V_{ocv}) or V_{ocv}(Q) corresponding to the second characteristic point;
calculating parameters of the lithium intercalations of the positive and negative electrodes including: calculating a positive electrode full discharge lithium intercalation amount x₀, a positive electrode full charge lithium intercalation amount x_{100%}, a negative electrode full discharge lithium intercalation amount y₀, and a negative electrode full charge lithium intercalation amount y_{100%}, according to the data of the first characteristic point, the second characteristic point, the third characteristic point, and the fourth characteristic point;
wherein the step of calculating the parameters of the lithium intercalation amounts of the positive and negative electrodes comprises solving equations of:
$$\{ \begin{matrix}{Q}_{1} = \frac{{x}_{1} - {x}_{0}}{{x}_{100 \%} - {x}_{0}} \\ {Q}_{2} = \frac{{x}_{2} - {x}_{0}}{{x}_{100 \%} - {x}_{0}}\end{matrix} , \{ \begin{matrix}{Q}_{1} = \frac{{y}_{1} - {y}_{0}}{{y}_{100 \%} - {y}_{0}} \\ {Q}_{2} = \frac{{y}_{2} - {y}_{0}}{{y}_{100 \%} - {y}_{0}}\end{matrix} ,$$
wherein x₂ is the positive electrode lithium intercalation amount obtained according to the first characteristic curve Vₚ(x) after a positive electrode potential Vₚ₂=V_{ocv2}+Vₙ₂ corresponding to the fourth characteristic point is calculated, and y₁ is the negative electrode lithium intercalation amount obtained according to the second characteristic curve Vₙ(y) after a negative electrode potential Vₙ₁=Vₚ₁−V_{ocv1} corresponding to the third characteristic point is calculated,
wherein the first characteristic point (x₁, Vₚ₁) is obtained through extremum points of a differential curve dVₚ(x)/dx of the first characteristic curve Vₚ(x); and the second characteristic point (y₂, Vₙ₂) is obtained through extremum points of a differential curve dVₙ(y)/dy of the second characteristic curve Vₙ(y);
wherein the third characteristic point (V_{ocv}, Q₁) is obtained by comparing a differential curve of the curve Q(V_{ocv}) with the differential curve dVₚ(x)/dx of the first characteristic curve Vₚ(x), or comparing a differential curve of the curve V_{ocv}(Q) with the differential curve dVₚ(x)/dx of the first characteristic curve Vₚ(x); and
wherein the fourth characteristic point (V_{ocv1}, Q₂) is obtained by comparing a differential curve of the curve Q(V_{ocv}) with the differential curve dVₙ(y)/dy of the second characteristic curve Vₙ(y), or comparing a differential curve of the curve V_{ocv}(Q) with the differential curve dVₙ(y)/dy of the second characteristic curve Vₙ(y).

2. The method of claim 1, wherein
when the differential curve Vₚ(x)/dx of the first characteristic curve Vₚ(x) has multiple extremum points, the first characteristic point (x₁, Vₚ₁) is obtained according to one extremum point having the largest or smallest value; and
when the differential curve dVₙ(y)/dy of the second characteristic curve Vₙ(y) has multiple extremum points, the second characteristic point (y₂, Vₙ₂) is obtained according to one extremum point having the largest or smallest value.

3. The method of claim 1, wherein the step of obtaining the curve Q(V_{ocv}) or V_{ocv}(Q) of the charging capacity and the open-circuit voltage of the lithium ion battery comprises:
measuring a terminal voltage curve of the lithium ion battery in the charging and discharging process with a small current rate, and approximating the terminal voltage curve as an open-circuit voltage curve V_{ocv}(t) of the lithium ion battery, wherein t is the charging and discharging time;
obtaining a charging capacity curve Q(t) of the lithium ion battery by integrating the charging and discharging current I; and
obtaining the curve Q(V_{ocv}) or V_{ocv}(Q) according to the open circuit voltage curve V_{ocv}(t) and the charging capacity curve Q(t) of the lithium ion battery.

4. The method of claim 3, wherein
the charging and discharging current I adopted in the charging and discharging process with the small current rate is a constant current, and the charging and discharging rate is not greater than C/20; and
the charging and discharging process with the small current rate includes small current rate charging processes and small current rate discharging processes; and the open circuit voltage curve V_{ocv}(t) and the charging capacity curve Q(t) are obtained by averaging data obtained from at least one of the small current rate charging processes and at least one of the small current discharge processes.

5. The method of claim 1, wherein the first characteristic curve Vₚ(x) and the second characteristic curve Vₙ(y) are obtained by half-cell testing, or by known characteristic curves of the positive electrode material and the negative electrode material.

6. The method of claim 3, wherein in the charging and discharging process with a small current rate, the lithium ion battery is placed in an environment with a constant temperature and a constant humidity.

7. An electronic device for detecting amounts of lithium intercalation in electrodes of a lithium ion battery, comprising:
a detection module and a data processing module, configured to perform nondestructive electrode detection of the lithium ion battery by using the above methods for detecting amounts of lithium intercalation in electrodes of a lithium ion battery,
wherein the detection module is configured to realize small current charging and discharging cycles of the lithium ion battery and simultaneously measure related data; and the data processing module comprises a calculation and analysis module for calculating and analyzing electrode lithium intercalation parameters of the lithium ion battery to obtain the amounts of electrode lithium intercalation in the lithium ion battery.

8. A battery management system, comprising:
the electronic device of claim 7, for nondestructive electrode detection for lithium ion batteries.
